(19) United States
(12) Patent Application Publication
(10) Pub. No.: US 2014/0097530 A1
(43) Pub. Date: Apr. 10, 2014

(54) INTEGRATED CIRCUIT PACKAGE

(71) Applicant: STS SEMICONDUCTOR & TELECOMMUNICATIONS CO., LTD., (US)

(72) Inventor: Kyung Teck BOO, Cheonan-si (KR)

(73) Assignee: STS SEMICONDUCTOR & TELECOMMUNICATIONS CO., LTD., Cheonan-si (KR)

(21) Appl. No.: 13/779,840

(22) Filed: Feb. 28, 2013

(30) Foreign Application Priority Data
Oct. 8, 2012 (KR) 1020120111558

(51) Int. Cl. H01L 25/07

(52) U.S. Cl. CPC H01L 25/074
USPC 257/676

(57) ABSTRACT

An integrated circuit package and a manufacturing method thereof are provided. The integrated circuit package can include a substrate provided with a circuit pattern, a first set of bonding fingers and a second set of bonding fingers, a first chip stack mounted on the substrate and having a plurality of first semiconductor chips stacked in a first direction in a stepped manner, each of the first semiconductor chips being provided with a first bonding pad at an end thereof on one side, a second chip stack mounted on the first chip stack and having a plurality of second semiconductor chips stacked in a second direction opposite to the first direction in a stepped manner.

### CROSS-REFERENCE TO RELATED APPLICATIONS

This application claims priority to KR 10-2012-0111558 filed on Oct. 28, 2012, and its entire disclosure is incorporated by reference herein.

### BACKGROUND OF THE INVENTION

1. Field of the Invention

The present invention relates to an integrated circuit package, and more particularly to an integrated circuit package with a stack of a plurality of semiconductor chips.

2. Description of the Related Art

In designing a product, the semiconductor industry generally seeks to lower cost, reduce weight, reduce size, increasing functionality and boosting performance. Semiconductor packaging is an important technology for achieving these goals.

Semiconductor packaging refers to a technology of forming signal input/output terminals to be connected to a main board using a lead frame or printed circuit board and performing a molding process for the same using an encapsulant in order to protect a single device or a semiconductor chip such as an integrated circuit, on which various electronic circuits and wires are stacked, from various environmental factors such as dust, humidity, and electrical and mechanical loads and to optimize or maximize the electrical performance of the semiconductor chip.

In the semiconductor industry, packaging technologies have developed to meet the demands for reduced size and mount reliability. For example, the demand for reduced size has accelerated the development of technology for fabricating a package having a size close to that of a chip, and the demand for mount reliability has highlighted the importance of packaging technology which can improve the efficiency of mounting and electrical and mechanical reliability after mounting.

With improvement in chip performance, semiconductor packaging technology has been challenged to provide a large number of input/output means to be electrically connected with the external components. To solve this challenge, research has been conducted to develop or improve packaging technologies such as ball grid array (BGA) type semiconductor packaging, fine-pitch BGA (FBGA) type semiconductor packaging and conventional packaging technology that uses lead frames.

Among those packaging technologies, the BGA package may have a capacity to accommodate a large number of input/output means, but as molding is performed only on one side thereof, molding results in warpage, namely warping of the package due to differences in coefficient of thermal expansion between the printed circuit board, silicon chip and epoxy molding compound (EMC), in contrast with a lead frame-based package, which has molding portions on both sides. Accordingly, the package disadvantageously makes adhesion of a solder ball to the lower side of a substrate difficult and increases the probability of mounting failure.

Thereby, the lead frame-based thin small outline package (TSOP) type is still widely used for a product requiring high reliability (such as an SSD).

For the TSOP type package, a semiconductor chip is mounted on the lead frame and encapsulated with an EMC to increase chip packing density.

FIG. 1 is a cross-sectional view illustrating the structure of a conventional TSOP type integrated circuit package.

With reference to FIG. 1, a conventional TSOP package has a structure in which a plurality of semiconductor chips 10, 11, 12 and 13 is stacked in a stepped manner on a lead frame 20 serving as a substrate. The semiconductor chips 10, 11, 12 and 13 are attached to the lead frame 20 in a lower layer or other semiconductor chips by an adhesive pad 10a, and electrically connected with the lead frame 20 through metal wires 30. Also, all portions of the package except the external leads are sealed using an encapsulant 40.

However, the above conventional TSOP type package has a disadvantage of not allowing a large number of semiconductor chips to be mounted within a limited thickness and area of the package since reduction in the thickness of the lead frame is limited and further an encapsulation space having a size exceeding a certain level should be arranged at the lower portion of the lead frame.

In addition, various types of warpage may occur depending on the positions of the semiconductor chips and the shape of the leads.

### SUMMARY OF THE INVENTION

Therefore, the present invention has been made in view of the above problems, and it is an object of the present invention to provide an integrated circuit package that can substantially compensate for defects resulting from the limits and disadvantages of the conventional technologies.

It is another object of the present invention to provide an integrated circuit package which allows a larger number of semiconductor chips to be stacked without increase in the thickness and area of the integrated circuit package.

In accordance with the present invention, the above and other objects can be accomplished by the provision of an integrated circuit package including a substrate provided with a circuit pattern, a first set of bonding fingers and a second set of bonding fingers, a first chip stack mounted on the substrate and having a plurality of first semiconductor chips stacked in a first direction in a stepped manner, each of the first semiconductor chips being provided with a first bonding pad at an end thereof on one side, a second chip stack mounted on the first chip stack and having a plurality of second semiconductor chips stacked in a second direction opposite to the first direction in a stepped manner, each of the second semiconductor chips being provided with a second bonding pad at an end thereof on an opposite side, a lead frame provided with first and second internal leads and first and second external leads, the internal leads being connected on the substrate, a plurality of first conductive wires for electrically connecting the first bonding pad to at least one of the first set of bonding fingers and the first internal lead, and a plurality of second conductive wires for electrically connecting the second bonding pad to at least one of the second set of bonding fingers and the second internal lead.

The integrated circuit package may further include a molding portion for sealing one surface of the substrate including the first and second chip stacks, the first and second internal leads and the first and second conductive wires.

The integrated circuit package may further include a circuit pattern exposed on a surface of the substrate opposite to the one surface of the substrate having the molding portion formed thereon, and a solder ball connected to the exposed circuit pattern.

Each of the first set of bonding fingers and the second set of bonding fingers may be arranged in a row.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view illustrating the structure of a conventional TSOP type integrated circuit package;

FIG. 2 is a cross-sectional view illustrating the structure of an integrated circuit package according to a first embodiment of the present invention;

FIG. 3 is a plan view illustrating wire bonding according to an exemplary embodiment of the present invention; and

FIG. 4 is a cross-sectional view illustrating the structure of an integrated circuit package according to a second embodiment of the present invention.

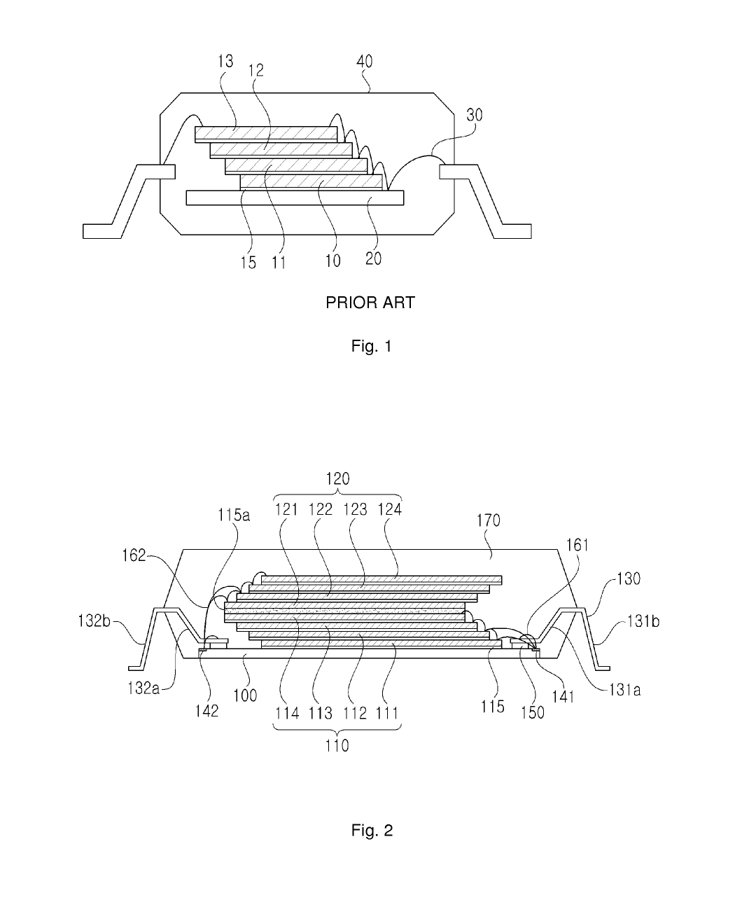

### DETAILED DESCRIPTION OF THE INVENTION

Reference will now be made in detail to the embodiments of the present invention, examples of which are illustrated in the accompanying drawings.

In describing the present invention, a description of well known functions and configurations will be omitted as deemed unnecessarily obscuring the essence of the present invention. Also, the terms used below have been defined in consideration of their functions in the present invention and the definitions thereof may be changed depending on the intention of a user or precedent. Therefore, the terms should be defined based on the entirety of the specification of the present invention.

FIG. 2 is a cross-sectional view illustrating the structure of an integrated circuit package according to a first embodiment of the present invention.

With reference to FIG. 2, the integrated circuit package according to the first embodiment of the present invention includes a substrate 100, a first chip stack 110, a second chip stack 120, a lead frame 130, first and second conductive wires 160 and a molding portion 170.

The substrate 100 is provided with boding fingers 140 at the edge of the upper surface thereof, on which the first chip stack 110 and second chip stack 120 are stacked. The boding fingers 140 can be divided into a first set of boding fingers 141 arranged in a row on the right side of the upper surface of the substrate 100 and a second set of boding fingers 142 arranged in a row on the left side of the upper surface of the substrate 100. The first boding fingers 141 are electrically connected with semiconductor chips 111 to 114 constituting the first chip stack 110, and the second bonding fingers 142 are electrically connected with semiconductor chips 121 to 124 constituting the second chip stack 120. Here, the substrate 100 may be an interposer substrate that serves to electrically connect the chips inside the package with an external printed circuit board (PCB) and support the semiconductor chips, or the PCB itself. The substrate 100 may be a plastic substrate or a ceramic substrate, and more specifically may be a plastic substrate having an epoxy core and electrical wiring.

The first chip stack 110 includes a plurality of first semiconductor chips 111 to 114 stacked in at least two layers on the upper surface of the substrate 100. The first semiconductor chips 111 to 114 are provided with a first bonding pad (not shown) at the end (edge) of the right side (one side) of the upper surfaces thereof, and are stacked from right to left (a first direction) in a stepped manner such that the first bonding pad is exposed.

The second chip stack 120 includes a plurality of second semiconductor chips 121 to 124 stacked in at least two layers on the upper surface of the substrate 100. The second semiconductor chips 121 to 124 are provided with a second bonding pad (not shown) at the end (edge) of the left side (the one side) of the upper surfaces thereof, and are stacked from left to right (a second direction) in a stepped manner such that the second bonding pad is exposed.

The semiconductor chips 111 to 114 and 121 to 124 respectively constituting the first chip stack 110 and the second chip stack 120 and the substrate 100 are attached to each other by an adhesive layer, e.g., an adhesive tape 115. The semiconductor chips 111 to 114 and 121 to 124 may have the same or different structures. Each of the semiconductor chips 111 to 114 and 121 to 124 may be provided with semiconductor devices such as a memory device, a logic device, a photoelectric device or a power device, and the semiconductor device may include various passive elements such as a resistor and a capacitor.

The lead frame 130 is provided with first and second internal leads 131a and 132a and first and second external leads 131b and 132b, and the first and second internal leads 131a and 132a are connected on the substrate 100 by the adhesive 150. The first internal lead 131a and first external lead 131b are provided for the semiconductor chips 111 to 114 of the first chip stack 110, and the second internal lead 132a and second external lead 132b are provided for the semiconductor chip 121 to 124 of the second chip stack 120.

The first conductive wires 161 are configured with wire members bonded between the first bonding pads (not shown) formed on the right side of the upper surfaces of the first semiconductor chips 111 to 114 and the first bonding fingers 141 or first leads 131a and 131b formed on the right side of the upper surface of the substrate 100 so as to electrically connect the first semiconductor chips 111 to 114 constituting the first chip stack 110 to the substrate 100 or lead frame 130.

The second conductive wires 162 are configured with wire members bonded between the bonding pads (not shown) formed on the left side of the upper surfaces of the second semiconductor chips 121 to 124 and the second boding fingers 142 or second leads 132a and 132b formed on the left side of the upper surface of the substrate 100 so as to electrically connect the second semiconductor chips 121 to 124 constituting the second chip stack 120 to the substrate 100 or lead frame 130.

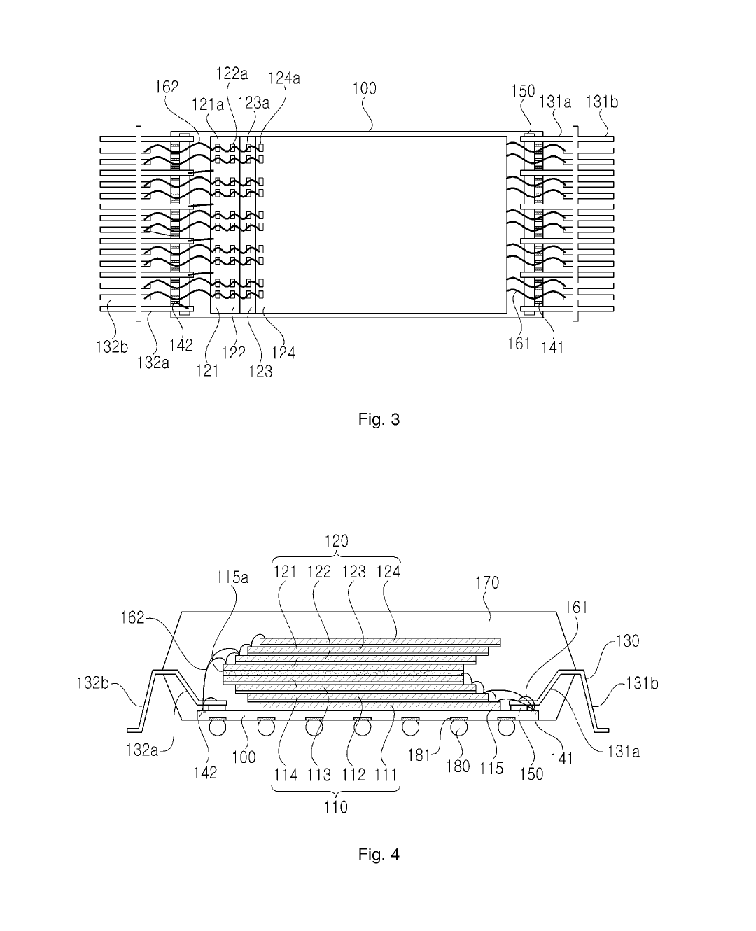

FIG. 3 is a plan view illustrating wire bonding according to an exemplary embodiment of the present invention. As shown in FIG. 3, the first semiconductor chips (not shown as they are positioned below the second semiconductor chips) and the second semiconductor chips 121 to 124 are electrically connected with external terminals through wire bonding of the first bonding pads or second boding pads 121a to 124a formed on the upper surfaces of the first and second semiconductor chips, and the wire bonding by the conductive wires 161 and 162 may be implemented in various combinations of the bonding fingers 141 and 142, the internal leads 131a and 132a and the external leads 131b and 132b.

With reference to FIG. 2, the molding portion 170 is formed by sealing the upper surface of the substrate 100 including the stacked semiconductor chips 111 to 114 and 121 to 124 and the conductive wires with an encapsulant, which is formed from, for example, an epoxy molding compound (EMC), and serves to protect the semiconductor chips not only from external stress such as shock and vibration, but also from dust and humidity.

FIG. 4 is a cross-sectional view illustrating the structure of an integrated circuit package according to a second embodiment of the present invention.

With reference to FIG. 4, the integrated circuit package according to the second embodiment includes a substrate 100, a first chip stack 110, a second chip stack 120, a lead frame 130, first and second conductive wires 160, a molding portion 170, and solder balls 180.

The integrated circuit package according to the illustrated embodiment, which is configured by adding the solder balls 180 for a BGA to the structure of the first embodiment shown in FIG. 2, has the same constituents as those of FIG. 2, except the solder balls 180, and therefore only the solder balls 180 will be described in this embodiment.

The solder balls 180, which are provided to electrically connect the semiconductor chips stacked on the substrate 100 to an external circuit, e.g., a PCB (not shown), are attached to external terminals 181 exposed at the lower surface of the substrate 100.

As such, the illustrated embodiment provides both terminals for the solder balls for the BGA and terminals for the lead frame and has the molding portion formed only on the upper surface of the substrate, thereby allowing a larger number of semiconductor chips to be stacked within a package having a limited thickness and area than other structures which have the molding portions formed both on the upper and lower surfaces of the substrate.

As is apparent from the above description, an integrated circuit package according to the present invention includes an insulation substrate as the base substrate, a plurality of semiconductor chips stacked on the upper surface of the substrate in a stepped manner, lead frames attached to both ends of the upper surface of the substrate to be electrically connected to external terminals, thereby making it possible to stack a larger number of semiconductor chips within a package having a limited thickness and area than other structures which have the molding portions formed on both the upper surface and lower surface of the substrate.

Also, the integrated circuit package according to the present invention is provided with both solder ball terminals for the BGA and terminals for the lead frame-based package, thereby allowing a larger number of semiconductor chips to be stacked within a package having a limited thickness and area than other structures which have the molding portions formed on both the upper and lower surfaces of the substrate.

Although a few embodiments of the present invention have been disclosed for illustrative purposes, those skilled in the art will appreciate that various modifications, additions and substitutions are possible, without departing from the scope and spirit of the invention, the scope of which is defined in the claims and their equivalents.

What is claimed is:

1. An integrated circuit package comprising:
a substrate provided with a circuit pattern, a first set of bonding fingers and a second set of bonding fingers;
a first chip stack mounted on the substrate and having a plurality of first semiconductor chips stacked in a first direction in a stepped manner, each of the first semiconductor chips being provided with a first bonding pad at an end thereof on one side;
a second chip stack mounted on the first chip stack and having a plurality of second semiconductor chips stacked in a second direction opposite to the first direction in a stepped manner, each of the second semiconductor chips being provided with a second bonding pad at an end thereof on an opposite side;
a lead frame provided with first and second internal leads and first and second external leads, the internal leads being connected on the substrate;
a plurality of first conductive wires for electrically connecting the first bonding pad to at least one of the first set of bonding fingers and the first internal lead; and
a plurality of second conductive wires for electrically connecting the second bonding pad to at least one of the second set of bonding fingers and the second internal lead.

2. The integrated circuit package according to claim 1, further comprising a molding portion for sealing one surface of the substrate including the first and second chip stacks, the first and second internal leads and the first and second conductive wires.

3. The integrated circuit package according to claim 2, further comprising:
a circuit pattern exposed on a surface of the substrate opposite to the one surface of the substrate having the molding portion formed thereon; and
a solder ball connected to the exposed circuit pattern.

4. The integrated circuit package according to claim 1, wherein each of the first set of bonding fingers and the second set of bonding fingers is arranged in a row.
